(19) United States
(12) Patent Application Publication
(10) Pub. No.: US 2026/0018445 A1
(43) Pub. Date: Jan. 15, 2026

(54) APPARATUS AND SYSTEM FOR TRANSFERRING SUBSTRATE

(71) Applicant: Samsung Electronics Co., Ltd., Suwon-si (KR)

(72) Inventors: Youngwook KIM, Suwon-si (KR); Sangmin KIM, Suwon-si (KR); Hyoengrak KIM, Suwon-si (KR); Yong-Jun AHN, Suwon-si (KR); Sangkyung LEE, Suwon-si (KR); Hyunwoo LEE, Suwon-si (KR); Min-Gu CHANG, Suwon-si (KR); Junhyuk CHANG, Suwon-si (KR)

(21) Appl. No.: 19/008,817

(22) Filed: Jan. 3, 2025

(30) Foreign Application Priority Data
Jul. 9, 2024 (KR) 10-2024-0090193

(51) Int. Cl. H01L 21/677; B65G 1/04

(52) U.S. Cl. CPC H01L 21/67724; B65G 1/04; H01L 21/6773; H01L 21/67733; B65G 2201/0297

(57) ABSTRACT

A substrate transfer system includes a main body on which a carrier configured to store a substrate is loaded, a first wheel assembly disposed inside the main body and configured to travel along a first rail extending in a first direction, a second wheel assembly disposed inside the main body and configured to travel along a second rail extending in a second direction different from the first direction, and a lift disposed inside the main body and configured to move the first wheel assembly up and down between a first lower position at which the first wheel assembly is in contact with the first rail and a first upper position higher than the first lower position, and to move the second wheel assembly up and down between a second lower position at which the second wheel assembly is in contact with the second rail and a second upper position higher than the second lower position.

### CROSS-REFERENCE TO RELATED APPLICATION

This application claims priority to Korean Patent Applications No. 10-2024-0090193, filed in the Korean Intellectual Property Office on Jul. 9, 2024, the entire contents of which are hereby incorporated by reference.

### BACKGROUND

### Technical Field

The present disclosure relates to a substrate transfer apparatus and a substrate transfer system including the same.

### Description of Related Art

Generally, a substrate processing apparatus that processes semiconductor substrates provides the substrates to or collects the substrates from the processing equipment using a carrier that holds a plurality of substrates therein, such as a front opening unified pod (FOUP), a front opening shipping box (FOSB), a run box, etc. The carrier may generally be transferred by an overhead hoist transport.

The overhead hoist transport transfers carriers with unprocessed substrates and loads them in an empty storage structure, and picks up carriers with processed substrates from the storage structure and carries them to the outside.

Meanwhile, the semiconductor factories are sensitive to generation of particles, and therefore, the storage systems installed inside of the semiconductor factories are required to maintain a high level of cleanliness.

### SUMMARY

In order to solve one or more problems (e.g., the problems described above and/or other problems not explicitly described herein), the present disclosure provides a substrate transfer apparatus and a substrate transfer system moving along a grid rail.

The present disclosure also provides a substrate transfer apparatus and a substrate transfer system including an elevation device having a compact structure.

The present disclosure also provides a substrate transfer apparatus and a substrate transfer system capable of suppressing the possibility that particles are generated, thus contributing to improved cleanliness.

The present disclosure also provides a substrate transfer apparatus and a substrate transfer system, which can be used in a semiconductor factory.

According to some example embodiments of the present disclosure, a substrate transfer apparatus may include a main body on which a carrier configured to store a substrate is loaded; a first wheel assembly disposed inside the main body, the first wheel assembly being configured to travel along a first rail extending in a first direction to move the main body; a second wheel assembly disposed inside the main body, the second wheel assembly being configured to travel along a second rail extending in a second direction different from the first direction to move the main body; and a lift disposed inside the main body and configured to move the first wheel assembly up and down between a first lower position at which the first wheel assembly is in contact with the first rail and a first upper position higher than the first lower position, and to move the second wheel assembly up and down between a second lower position at which the second wheel assembly is in contact with the second rail and a second upper position higher than the second lower position.

According to some example embodiments of the present disclosure, a substrate transfer apparatus may include a main body on which a carrier is configured to be loaded and which is configured to move in a first direction or a second direction perpendicular to the first direction; a first wheel assembly disposed inside the main body, and comprising a first shaft extending in the second direction and a first traveling wheel rotatably coupled to the first shaft; a second wheel assembly disposed inside the main body, and comprising a second shaft extending in the first direction and a second traveling wheel rotatably coupled to the second shaft; and a lift disposed inside the main body and configured to move each of the first wheel assembly and the second wheel assembly up and down, wherein the lift comprises: a drive motor comprising a drive shaft extending in the second direction and a drive motor configured to generate a rotational force, the drive motor being coupled to the second wheel assembly; a drive plate coupled to the first wheel assembly and extending in the first direction; and a link assembly coupled to the drive motor and the drive plate.

According to some example embodiments of the present disclosure, a substrate transfer system may include a grid rail comprising a first rail extending in a first direction and a second rail extending in a second direction perpendicular to the first direction; and a substrate transfer apparatus configured to move in the first direction or the second direction on the grid rail to transfer a substrate, wherein the substrate transfer apparatus comprises: a main body on which a carrier configured to store the substrate is loaded; a first wheel assembly comprising a first shaft extending along the second direction, a first traveling wheel rotatably coupled to the first shaft, and a moving plate coupled with the first shaft, the first wheel assembly being configured to move the main body along the first rail; a second wheel assembly comprising a second shaft extending along the first direction, a second traveling wheel rotatably coupled to the second shaft, and a base plate coupled with the second shaft, the second wheel assembly being configured to move the main body along the second rail; and a lift configured to move the first wheel assembly up and down between a first lower position at which the first wheel assembly is in contact with the first rail and a first upper position higher than the first lower position, and to move the second wheel assembly up and down between a second lower position at which the second wheel assembly is in contact with the second rail and a second upper position higher than the second lower position.

According to some example embodiments of the present disclosure, the substrate transfer apparatus may move along the grid rail.

According to some example embodiments of the present disclosure, the substrate transfer apparatus may include the elevation device having a compact structure.

According to some example embodiments of the present disclosure, the substrate transfer apparatus may improve cleanliness by employing a shielding structure.

According to some example embodiments of the present disclosure, the substrate transfer apparatus and the substrate transfer system may include a structure for reducing particle generation and may be used in a semiconductor factory.

### BRIEF DESCRIPTION OF THE DRAWINGS

FIG. 1 is a perspective view illustrating a substrate transfer system according to some example embodiments.

FIG. 2 is a perspective view illustrating a substrate transfer apparatus according to some example embodiments.

FIGS. 3 to 5 are perspective views illustrating a partial configuration of the substrate transfer apparatus of FIG. 2.

FIG. 6 is a view illustrating an elevation device of a substrate transfer apparatus according to some example embodiments.

FIG. 7 is a view illustrating an elevation device of a substrate transfer apparatus from a different angle according to some example embodiments.

FIG. 8 is an exploded view of the elevation device of FIG. 6.

FIGS. 9 to 11 are views provided to explain an operation of the elevation device according to some example embodiments.

FIG. 12 is a cross-sectional view illustrating an elevation device in a coupled state according to some example embodiments.

FIG. 13 is a cross-sectional view illustrating an elevation device with some components in a decoupled state according to some example embodiments.

FIG. 14 is a cross-sectional view illustrating a link assembly in a disassembled state according to some example embodiments.

### DETAILED DESCRIPTION

A substrate transfer apparatus and a substrate transfer system according to some example embodiments of the present disclosure will be described in detail with reference to the drawings.

An item, layer, or portion of an item or layer described as “extending” or as extending “lengthwise” in a particular direction has a length in the particular direction and a width perpendicular to that direction, where the length is greater than the width.

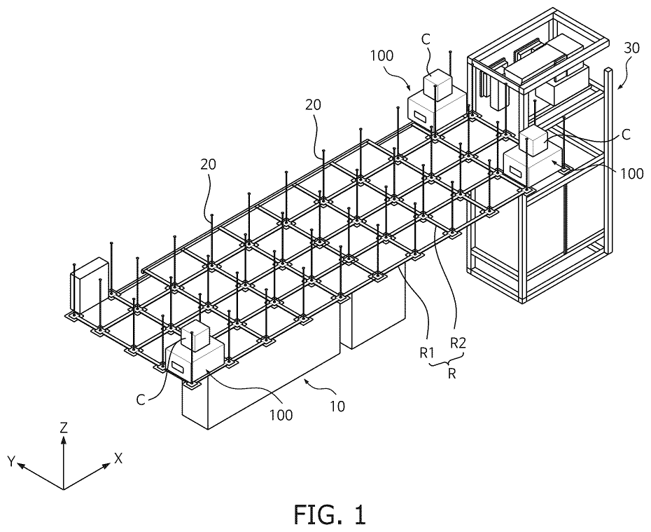

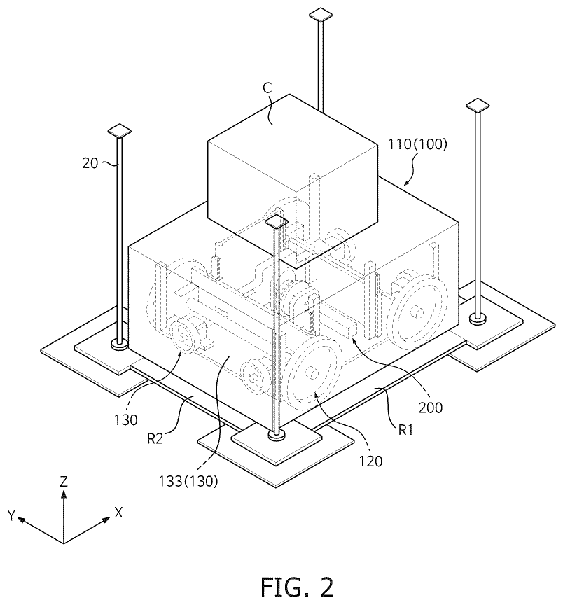

FIG. 1 is a perspective view illustrating a logistics storage system according to some example embodiments. FIG. 2 is a perspective view illustrating a substrate transfer apparatus according to some example embodiments.

Referring to FIG. 1, a substrate transfer system 1 according to some example embodiments may include a grid rail R, a substrate storage device 10, a supporter 20, a transport device 30, and a substrate transfer apparatus 100.

The grid rail R may include a first rail R1 extending in a first direction X and a second rail R2 extending in a second direction Y. The first rail R1 and the second rail R2 may be provided in plurality. The plurality of first rails R1 may be spaced apart from each other in the second direction Y. The plurality of second rails R2 may be spaced apart from each other in the first direction X. As such, the grid rail R may be arranged in a grid shape. The first rails R1 and the second rails R2 may intersect each other.

Hereinafter, the first direction X and the second direction Y may be different from each other. The first direction X and the second direction Y may be parallel to the floor of a semiconductor factory. The first direction X and the second direction Y may be orthogonal to each other. A third direction Z may be orthogonal to each of the first direction X and the second direction Y. The third direction Z may be perpendicular to the floor of the semiconductor factory.

The grid rail R may be fixed to the ceiling in the semiconductor factory. The grid rail R may be fixed to the ceiling by the supporter 20. The supporter 20 may extend in the third direction Z. The supporter 20 may be provided in a plurality. Each of the plurality of supporters 20 may be disposed at a corresponding intersecting point between the plurality of first rails R1 and the plurality of second rails R2.

The substrate storage device 10 may be disposed adjacent to the grid rail R. For example, the substrate storage device 10 may be disposed under the grid rail R. The substrate storage device 10 may have a plurality of storage spaces.

The substrate storage device 10 may store a carrier C on which a substrate is mounted. The carrier C may store the substrate. The substrate may be a semiconductor wafer. The carrier C may include a front opening unified pod (FOUP), a front opening shipping box (FOSB), a run box, etc.

The transport device 30 may be located on the floor of the semiconductor factory. The transport device 30 may move the substrate transfer apparatus 100 to be described below from the grid rail R to the floor, or conversely, may move the substrate transfer apparatus 100 from the floor to the grid rail R. For example, the substrate transfer apparatus 100 traveling on the grid rail R may be transferred to the floor of the semiconductor factory for repair via the transport device 30.

The substrate transfer apparatus 100 may include a main body 110. The main body 110 of the substrate transfer apparatus 100 may be loaded with a carrier C. For example, the main body 110 of the substrate transfer apparatus 100 may be disposed above the grid rail R, and the carrier C may be loaded on an upper surface of the main body 110. As another example, the main body 110 of the substrate transfer apparatus 100 may be disposed under the grid rail R, and the carrier C may be loaded on a lower surface of the main body 110. In some example embodiments, the main body 110 may include a separate structure for stably loading the carrier C.

The main body 110 may form an exterior appearance of the substrate transfer apparatus 100. For example, the main body 110 may have a hexahedral shape with one or more surfaces open. An open surface of the one or more open surfaces of the main body 110 may be covered by a base plate 133 of a second traveling part 130 to be described later. The main body 110 may cover a first traveling part 120, the second traveling part 130, an elevation device 200, etc.

The first traveling part 120, the second traveling part 130, and the elevation device 200 may be disposed inside the main body 110. In some example embodiments, the inside of the main body 110 may mean the inside of the main body 110 in a planar direction (i.e., in XY direction), although the present disclosure is not limited thereto. The first traveling part 120, the second traveling part 130, and the elevation device 200 may be accommodated inside the main body 110. The first traveling part 120, the second traveling part 130, and the elevation device 200 may be disposed in a space formed inside of the main body 110. The main body 110 may prevent the first traveling part 120, the second traveling part 130, and the elevation device 200 from being exposed to the outside to a certain extent. Accordingly, the main body 110 may prevent particles that may be generated in the first traveling part 120, the second traveling part 130, and the elevation device 200 from being scattered to the outside of the main body 110.

Operation of any one or more of the first traveling part 120, the second traveling part 130, and the elevation device 200 may be controlled by a controller. Although not illustrated, a controller can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The main body 110 may define the inside and outside of the substrate transfer apparatus 100. For example, the carrier C loaded on the main body 110 may be defined as being disposed outside of the main body. In addition, the first traveling part 120, the second traveling part 130, and the elevation device 200, etc. covered by the main body 110 may be defined as being disposed inside the main body 110.

The substrate transfer apparatus 100 may travel on the grid rail R. Specifically, the substrate transfer apparatus 100 may travel on an upper surface the grid rail R. In some example embodiments, the substrate transfer apparatus 100 may be disposed on the grid rail R. However, the present disclosure is not limited thereto, and some components of the substrate transfer apparatus 100 may be disposed under the grid rail R.

The substrate transfer apparatus 100 may travel along the first rail R1 or the second rail R2 on the grid rail R. The first traveling part 120 of the substrate transfer apparatus 100 may travel along the first rail R1. The first traveling part 120 may travel along the first rail R1 to move the main body 110. The second traveling part 130 of the substrate transfer apparatus 100 may travel along the second rail R2. The second traveling part 130 may travel along the second rail R2 to move the main body 110.

The substrate transfer apparatus 100 may move along the first rail R1 in the first direction X. The substrate transfer apparatus 100 may move along the second rail R2 in the second direction Y. For example, the substrate transfer apparatus 100 may move along the first rail R1 in the first direction X, and at the intersecting point between the first rail R1 and the second rail R2, may move to the second rail R2. Conversely, the substrate transfer apparatus 100 may move along the second rail R2 in the second direction Y, and at the intersecting point between the first rail R1 and the second rail R2, may move to the first rail R1.

The substrate transfer apparatus 100 may travel along the first rail R1 extending in the first direction X, and perform an interface operation with other devices. The substrate transfer apparatus 100 may travel along the second rail R2 extending in the second direction Y, and perform an interface operation with other devices. Alternatively, the substrate transfer apparatus 100 may travel along the first rail R1 and turn the direction to travel along the second rail R2, or travel along the second rail R2 and turn the direction to travel along the first rail R1, and perform an interface operation with other devices.

When the substrate transfer apparatus 100 travels along the first rail R1 and travels along the second rail R2, or when it travels along the second rail R2 and travels along the first rail R1, the substrate transfer apparatus 100 may turn the direction of travel. Hereinafter, the traveling structure of the substrate transfer apparatus 100 will be described.

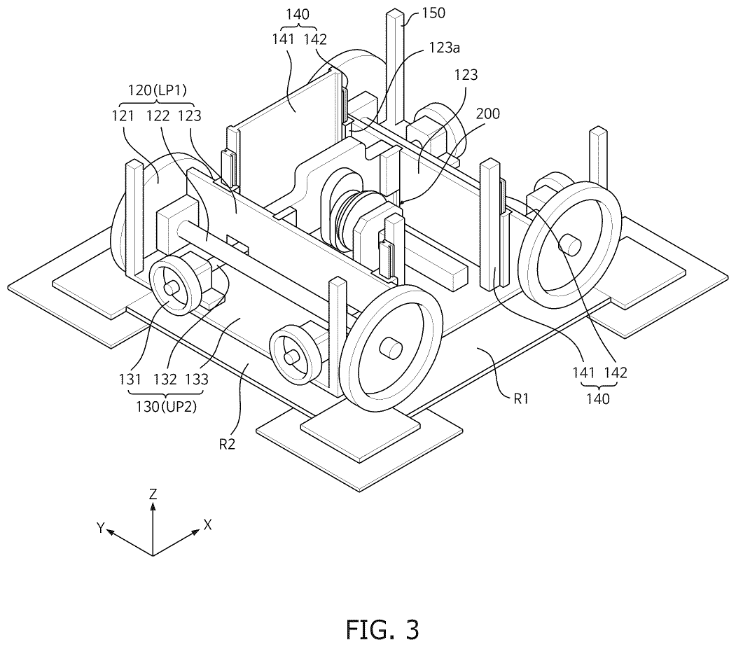

FIGS. 3 to 5 are perspective views illustrating a partial configuration of the substrate transfer apparatus of FIG. 2.

Referring to FIGS. 3 to 5, the substrate transfer apparatus 100 according to some example embodiments may include a main body 110, a first traveling part 120 (e.g., a first wheel assembly), a second traveling part 130 (e.g., a second wheel assembly), an elevation device 200 (e.g., a lift), a moving guide 140 (e.g., a moving guide plate), and a support frame 150. The main body 110 may cover the first traveling part 120, the second traveling part 130, and the elevation device 200. The first traveling part 120, the second traveling part 130, and the elevation device 200 may be disposed inside the main body 110.

The first traveling part 120 may include a first traveling wheel 121, a first shaft 122, and a moving plate 123. The first traveling part 120 may travel along the first rail R1 on the first rail R1.

The first traveling wheel 121 may perform a rolling motion in the first direction X. The first shaft 122 may extend in the second direction Y. The first traveling wheels 121 may be rotatably coupled to either end of the first shaft 122. The first shaft 122 and the first traveling wheels 121 coupled to the ends of the first shaft 122 may constitute a first wheel assembly. The first wheel assembly may be provided in a plurality. For example, two first wheel assemblies may be provided. In this case, the substrate transfer apparatus 100 may include two first shafts 122 and four first traveling wheels 121 coupled to the ends of the first shafts 122. However, this is only an example, and the first wheel assembly may be provided in a larger number.

The moving plate 123 may have a plate shape extending in the second direction Y. However, the present disclosure are not limited thereto, and the moving plate 123 may have various shapes, such as a bar shape. The first wheel assembly may be coupled to the moving plate 123. Specifically, the first shaft 122 may be coupled to the moving plate 123. As used herein, the first wheel assembly may refer to the first shaft 122 combined with the first traveling wheels 121 at the ends of the first shaft, or the first wheel assembly may refer to the first shaft 122 combined with the first traveling wheels 121 at the ends of the first shaft 122 and further combined with the moving plate 123. For example, a connecting member having a center hole formed therein may be coupled to both sides of the moving plate 123, and the first shaft 122 may be passed through the hole and coupled to the connecting member. The moving plate 123 may be moved in the third direction Z by the elevation device 200 to be described below, and the first wheel assembly may be moved integrally with the moving plate 123. That is, the first traveling wheel 121, the first shaft 122, and the moving plate 123 may move integrally in the third direction Z.

The moving plate 123 may include a guide portion 123a to be movably coupled with a moving guide 140 to be described below. The guide portion 123a may be coupled to the moving guide 140, limiting movement of the moving plate 123 in the first direction X and the second direction Y to allow for reciprocating in the third direction Z (e.g., in only the third direction Z).

When two first wheel assemblies are provided, two moving plates 123 may also be provided. That is, the first wheel assemblies and the moving plates 123 may each be coupled. Each of the first shafts 122 may be coupled to a respective moving plate 123.

Each of the moving plates 123 may be spaced apart from each other in the first direction X. The four first traveling wheels 121 coupled to their respective first shafts 122 may be in contact with the grid rail R at four respective portions of the grid rail R. The two first shafts 122 may be arranged such that the center of gravity of the substrate transfer apparatus is located within contacting portions between the four first traveling wheels 121 and the grid rail R.

The second traveling part 130 may include a second traveling wheel 131, a second shaft 132, and a base plate 133. The second traveling part 130 may travel along the second rail R2 on the second rail R2.

The second traveling wheel 131 may perform a rolling motion in the second direction Y. The second shaft 132 may extend in the first direction X. The second traveling wheels 131 may be rotatably coupled to either end of the second shaft 132. The second shaft 132 and the second traveling wheels 131 coupled to the ends of the second shaft 132 may constitute a second wheel assembly. The second wheel assembly may be provided in a plurality. For example, two second wheel assemblies may be provided. In this case, the substrate transfer apparatus 100 may include two second shafts 132 and four second traveling wheels 131 coupled to the ends of the second shafts 132. However, this is only an example, and the second wheel assembly may be provided in a larger number.

The base plate 133 may be disposed under the main body 110. The base plate 133 may cover a lower portion of the main body 110. The base plate 133 may be parallel to the floor of the semiconductor factory. The second wheel assembly may be coupled to the base plate 133. Specifically, the second shaft 132 of the second wheel assembly may be coupled to the base plate 133. As used herein, the second wheel assembly may refer to the second shaft 132 combined with the second traveling wheels 131 at the ends of the second shaft 132, or the second wheel assembly may refer to the second shaft 132 combined with the second traveling wheels 131 at the ends of the second shaft 132 and further combined with the base plate 133. For example, a connecting member having a center hole formed therein may be coupled to both sides of the base plate 133, and the second shaft 132 may be passed through the hole and coupled to the connecting member. The base plate 133 may be moved in the third direction Z by the elevation device 200 to be described below, and the second wheel assembly may be moved integrally with the base plate 133. That is, the second traveling wheel 131, the second shaft 132, and the base plate 133 may move integrally in the third direction Z.

When two second wheel assemblies are provided, each of the second shafts 132 may be disposed to be spaced apart from each other in the second direction Y on the base plate 133. The four second traveling wheels 131 coupled to their respective second shafts 132 may be in contact with the grid rail R at four respective portions of the grid rail R. The two second shafts 132 may be arranged such that the center of gravity of the substrate transfer apparatus is located within contacting portions between the four second traveling wheels 131 and the grid rail R.

For example, the second shaft 132 may be coupled at an upper portion of the base plate 133. However, the present disclosure is not limited thereto, and the second shaft 132 may also be coupled to a lower portion of the base plate 133.

The first traveling wheel 121 of the first traveling part 120 and the second traveling wheel 131 of the second traveling part 130 may have different diameters. For example, the diameter of the first traveling wheel 121 may be greater than the diameter of the second traveling wheel 131. Since the diameter of the first traveling wheel 121 has a larger diameter, the vertical level of the first shaft 122 may be higher than the vertical level of the second shaft 132. Accordingly, there may be no interference between the first shaft 122 and the second shaft 132. Specifically, the vertical level of the first shaft 122 may correspond to the radius of the first traveling wheel 121, and the vertical level of the second shaft 132 may correspond to the radius of the second traveling wheel 131. The radius of the first traveling wheel 121 may be greater than the radius of the second traveling wheel 131. That is, the first shaft 122 may be positioned higher than the second shaft 132. However, the present disclosure is not limited thereto, and the diameter of the first traveling wheel 121 may be smaller than the diameter of the second traveling wheel 131.

The moving guide 140 may guide the movement of the first traveling part 120 that is moved up and down by the elevation device 200, which will be described later. The moving guide 140 may be coupled to the moving plate 123. The moving guide 140 may guide the moving plate 123 to move in the third direction Z. The moving guide 140 may be disposed on the base plate 133.

The moving guide 140 may include a guide body 141 and a guide rail 142. The guide body 141 may be coupled to the base plate 133. That is, the guide body 141 may move integrally with the base plate 133. The guide body 141 may extend in the third direction Z. The guide body 141 may guide the movement of the moving plate 123 in the third direction Z. The guide body 141 may be disposed perpendicular to the moving plate 123. For example, the guide body 141 may extend along the first direction X, and the moving plate 123 may extend along the second direction Y.

The guide rail 142 may be disposed on one side of the guide body 141. The guide rail 142 may extend along the third direction Z. The guide rail 142 may be disposed on one side of the guide body 141 in the first direction X. The guide rail 142 may be positioned between the guide body 141 and the guide portion 123a of the moving plate 123. The guide rail 142 may be slidably coupled to the guide portion 123a of the moving plate 123. For example, when two moving plates 123 are provided, there may be two guide rails 142 with one disposed on each side of the guide body 141 in the first direction X. Alternatively, two guide bodies 141 may be provided to correspond to their respective moving plates 123. Each of the guide rails 142 may be slidably coupled to the guide portion 123a of their respective moving plate 123. Although it is illustrated that the guide rail 142 and the guide portion 123a are coupled in a male-female configuration, the present disclosure is not limited thereto.

The support frame 150 may be disposed on the base plate 133. The support frame 150 may be disposed at a corner portion of the base plate 133. The support frame 150 may extend in the third direction Z. The main body 110 (see FIG. 2) may be coupled to the second traveling part 130 by the support frame 150. The main body 110 may be coupled to the support frame 150 to form an exterior appearance of the substrate transfer apparatus 100, and may cover the first traveling part 120, the second traveling part 130, and the elevation device 200, etc. The main body 110 may be coupled to the second traveling part 130 to move integrally with the second traveling part 130. However, the present disclosure is not limited thereto, and the main body 110 may be coupled to the first traveling part 120 to move integrally with the first traveling part 120.

The elevation device 200 may move the first traveling part 120 up and down between a first lower position LP1, at which the first traveling part 120 is in contact with the first rail R1, and a first upper position UP1 higher than the first lower position LP1, and may move the second traveling part 130 up and down between a second lower position LP2, at which the second traveling part 130 is in contact with the second rail R2, and a second upper position UP2 higher than the second lower position LP2. The reference point of the first lower position LP1 and the first upper position UP1 may be a part of the configuration of the first traveling part 120 (e.g., the lowest point of the first traveling wheel 121). Similarly, the reference point of the second lower position LP2 and the second upper position UP2 may be a part of the configuration of the second traveling part 130 (e.g., the lowest point of the second traveling wheel 131).

Hereinafter, the first upper position UP1 and the second upper position UP2 may be higher than the first lower position LP1 and the second lower position LP2, respectively. Accordingly, at the first upper position UP1, the first traveling wheel 121 may not be in contact with the first rail R1, and at the second upper position UP2, the second traveling wheel 131 may not be in contact with the second rail R2.

Referring to FIG. 3, the first traveling wheel 121 may be in contact with the first rail R1 so that the substrate transfer apparatus travels along the first direction X. In this case, the second traveling wheel 131 may not be in contact with the second rail R2.

At an intersecting point between the first rail R1 and the second rail R2, the elevation device 200 may turn the direction of travel of the substrate transfer apparatus. The elevation device 200 may turn the direction of the substrate transfer apparatus so that the substrate transfer apparatus, which was traveling along the first rail R1 in the first direction X, now travels along the second rail R2 in the second direction Y. At the intersecting point between the first rail R1 and the second rail R2, the elevation device 200 may lower the second traveling part 130 into contact with the second rail R2, and raise the first traveling part 120 away from the contact with the first rail R1.

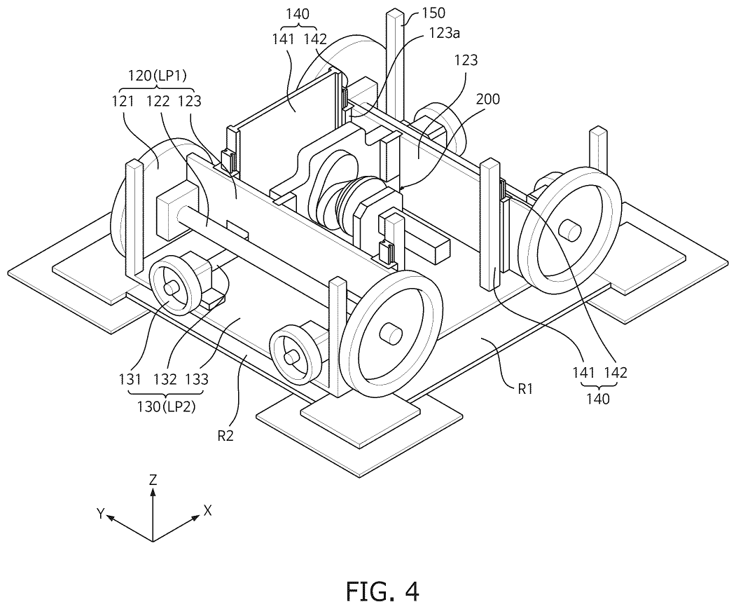

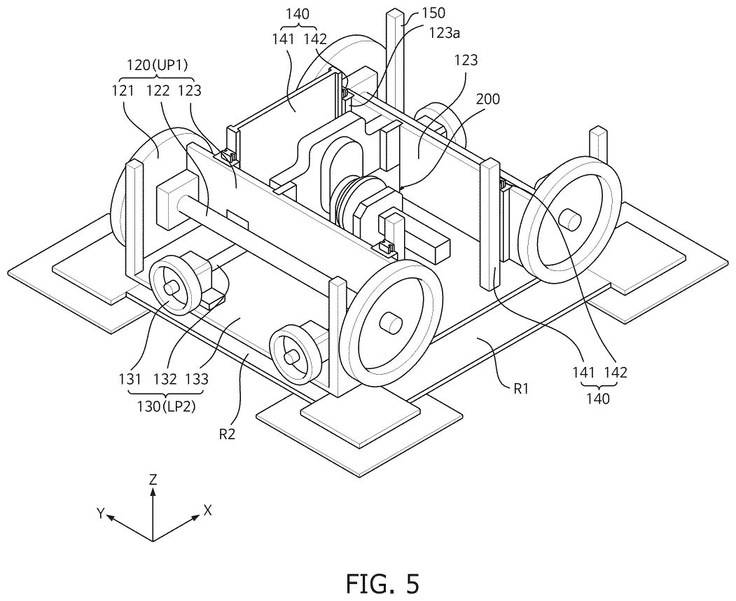

Referring to FIGS. 4 and 5, at the intersecting point between the first rail R1 and the second rail R2, the elevation device 200 may lower the second traveling part 130 from the second upper position UP2 to the second lower position LP2, and raise the first traveling part 120 from the first lower position LP1 to the first upper position UP1. As a result, the first traveling wheel 121 may not be in contact with the first rail R1, and the second traveling wheel 131 may be in contact with the second rail R2.

Conversely, the elevation device 200 may turn the direction of the substrate transfer apparatus so that the substrate transfer apparatus, which was traveling along the second rail R2 in the second direction Y, now travels along the first rail R1 in the first direction X. At the intersecting point between the first rail R1 and the second rail R2, the elevation device 200 may lower the first traveling part 120 into contact with the first rail R1, and raise the second traveling part 130 away from the contact with the second rail R2.

At the intersecting point between the first rail R1 and the second rail R2, the elevation device 200 may lower the first traveling part 120 from the first upper position UP1 to the first lower position LP1, and raise the second traveling part 130 from the second lower position LP2 to the second upper position UP2.

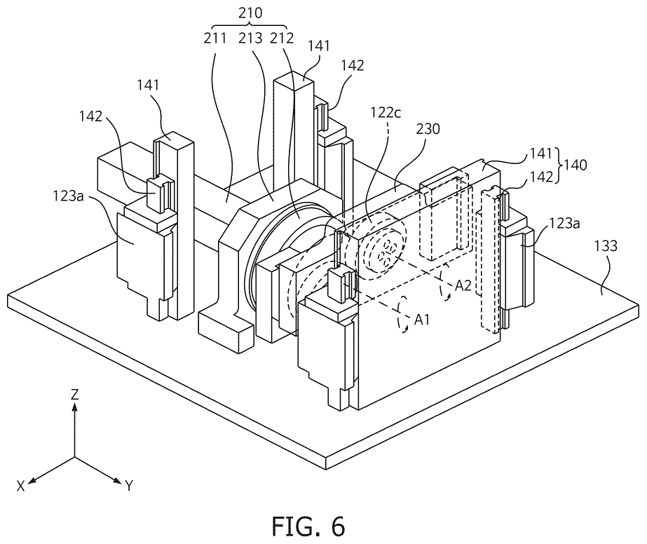

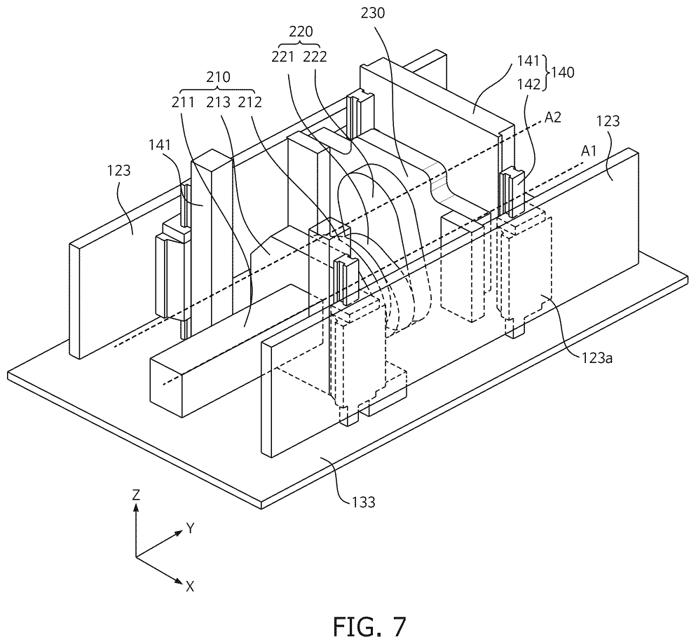

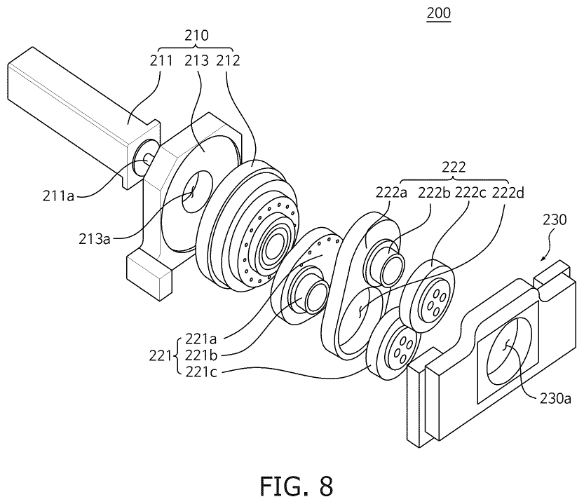

FIG. 6 is a view illustrating an elevation device of a substrate transfer apparatus according to some example embodiments. FIG. 7 is a view illustrating an elevation device of a substrate transfer apparatus from a different angle according to some example embodiments. FIG. 8 is an exploded view of the elevation device of FIG. 6.

Referring to FIGS. 6 to 8, the elevation device 200 may include a drive device 210 (e.g., a drive motor), a link assembly 220, and a drive plate 230.

The elevation device 200 may be disposed on the base plate 133. The elevation device 200 may be coupled to an upper surface of the base plate 133. The drive device 210 may be coupled to the second traveling part 130. Specifically, the drive device 210 may be coupled to an upper surface of the base plate 133 of the second traveling part 130. The drive device 210 may move integrally with the base plate 133 in the third direction Z.

The drive device 210 may include a drive motor 211, a reducer 212, and a housing 213.

The drive motor 211 may generate a rotational force. The drive motor 211 may be controlled by a controller. The drive motor 211 may include a drive shaft 211a that transmits a rotational force. The drive shaft 211a may extend in the second direction Y. The drive shaft 211a may transmit a rotational force. The reducer 212 may reduce the rotational speed generated by the drive motor 211, thereby increasing the torque. The reducer 212 may be connected to the drive shaft 211a. The rotational force generated by the drive motor 211 may be transmitted to the reducer 212 through the drive shaft 211a. The housing 213 may have a shaft hole 213a formed therein for the drive shaft 211a to pass through. The housing 213 may be disposed between the drive motor 211 and the reducer 212. The drive motor 211 and the reducer 212 may be coupled to either side of the housing 213. The drive motor 211 and the reducer 212 may cover either side of the shaft hole 213a.

The housing 213 may be coupled to the second traveling part 130. Specifically, the housing 213 may be coupled to the base plate 133 of the second traveling part 130. That is, each component of the drive device 210 may be directly or indirectly coupled to the base plate 133. However, the drive motor 211 is only an example of a drive source, and other drive sources capable of generating a rotational force may be used, such as a belt pulley.

The link assembly 220 may include a first link 221 and a second link 222.

The first link 221 may be coupled to the drive device 210. The first link 221 may be coupled to the reducer 212 of the drive device 210. The first link 221 may be rotatably coupled to the drive device 210 about the drive shaft 211a. The first link 221 may be coupled to the reducer 212. The interface between the first link 221 and the reducer 212 may extend in a plane substantially perpendicular to the direction of extension of the drive shaft 211a. The first link 221 may be coupled to the reducer 212 via a fastening member such as a bolt, etc. However, the coupling method is not limited thereto.

The first link 221 may be rotated as the rotational force generated by the drive motor 211 is transmitted through the drive shaft 211a to the reducer 212. The first link 221 may be rotated by the rotational force transmitted to the reducer 212. The first link 221 may rotate about a rotation axis A1 (see FIGS. 6 and 7), which is the axis extended from the drive shaft 211a.

The first link 221 may include a first link body 221a, a first joint 221b, and a first bearing 221c. The first link body 221a may be coupled to the reducer 212. The first joint 221b may protrude from the first link body 221a in a direction parallel to the axis A1. The first joint 221b may be formed at a predetermined length in a direction perpendicular to the axis A1 (e.g., in a radial direction of the axis A1) apart from the coupling portion between the first link body 221a and the reducer 212. The rotation radius when the first link 221 is in a rotational motion may correspond to a distance from the center of the coupling portion between the first link body 221a and the reducer 212 to the center of the first joint 221b.

The first bearing 221c may be coupled to the first joint 221b. The first joint 221b and the first bearing 221c, while being coupled together, may be coupled to the second link 222. Specifically, the first joint 221b and the first bearing 221c, while being coupled together, may be accommodated in a joint hole 222d of the second link 222 to be described below. The first joint 221b and the first bearing 221c, while being coupled together, may be accommodated in the joint hole 222d of the second link 222, so that the first link 221 and the second link 222 may be rotatably connected to each other.

The second link 222 may be coupled to the first link 221. The second link 222 may move according to rotation of the first link 221. The second link 222 may be rotatably coupled to the first link 221. The second link 222 may rotationally move along a portion of a circle, by the rotational motion of the first link 221. The second link 222 may be coupled to the drive plate 230 to be described below. The second link 222 may rotate while being coupled to the drive plate 230.

The second link 222 may include a second link body 222a, a second joint 222b, a second bearing 222c, and a joint hole 222d.

The first joint 211b and the first bearing 211c of the first link 221, while being coupled together, may be accommodated in the joint hole 222d of the second link 222. While the first link 221 is rotated by the drive device 210, the first bearing 211c may rotatably support the first joint 211b.

The second link 222 may be rotatably coupled to the drive plate 230. The second joint 222b may protrude from the second link body 222a in a direction parallel to the axis A1. The second joint 222b may be coupled to the second bearing 222c. The second joint 222b and the second bearing 222c, while being coupled together, may be accommodated in a plate hole 230a of the drive plate 230 to be described below. The second link 222 may perform a rotational motion about a rotation axis A2 at the coupling portion between the second link 222 and the drive plate 230. The rotation radius when the second link 222 is in the rotational motion may correspond to a distance between an axis passing through the center of the second joint 222b and an axis passing through the center of the first joint 211b.

The drive plate 230 may be coupled to the link assembly 220. The drive plate 230 may include the plate hole 230a for coupling with the link assembly 220. The plate hole 230a may be a groove that does not pass completely through the drive plate 230. The drive plate 230 may be rotatably coupled to the second link 222. The second joint 222b and the second bearing 222c of the second link 222, while being coupled together, may be accommodated in the plate hole 230a. The second link 222, while being accommodated in the plate hole 230a, may perform a rotational motion about the plate hole 230a.

The drive plate 230 may be coupled to the first traveling part 120. The drive plate 230 may be coupled to the moving plate 123 of the first traveling part 120. The drive plate 230 may be configured such that the rotational force generated by the drive device 210 is converted into linear motion through the link assembly 220. The moving plate 123 may be coupled to the moving guide 140 to be restricted from moving in the first direction X and the second direction Y and allowed to move in the third direction Z. That is, the drive plate 230 may move linearly in the third direction Z. The moving plate 123 coupled to the drive plate 230 may linearly move together in the third direction Z.

As such, the first link 221 and the second link 222 may convert the rotational motion of the drive device 210 into the linear motion of the drive plate 230 and the moving plate 123.

Hereinafter, the operation mechanism of the elevation device according to some example embodiments will be described.

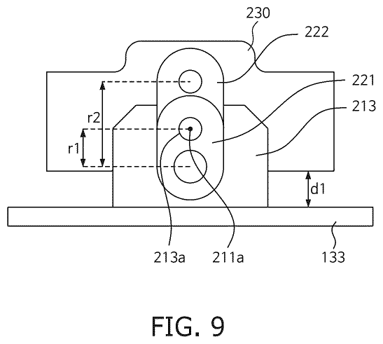

FIGS. 9 to 11 are views provided to explain an operation of the elevation device.

FIGS. 9 to 11 are views corresponding to FIGS. 3 to 5, respectively.

Referring to FIGS. 9 to 11, the drive device 210 may be coupled to the base plate 133. The link assembly 220 and the drive plate 230 may be moved by a driving force generated by the drive device 210.

The drive device 210 coupled to the base plate 133 may generate a driving force. The drive device 210 may rotate the first link 221 using the drive shaft 211a as a rotation axis. The first link 221 may have a first rotation radius r1. By the rotation of the first link 221, the second link 222 may be moved. By the rotation of the first link 221, the second link 222 may reciprocate along a portion of a circle having a second rotation radius r2. The second link 222 may have a second rotation radius r2.

The drive plate 230 may ascend or descend from the drive device 210 in the third direction Z. The drive plate 230 may reciprocate in an up/down direction within a distance range that extends from, at its lowest, a difference between the first rotation radius r1 and the second rotation radius r2 to, at its highest, a sum of the first rotation radius r1 and the second rotation radius r2.

Referring to FIGS. 3 and 9, the first traveling part 120 may be positioned at the first lower position LP1. With the first traveling part 120 being at the first lower position LP1, the first traveling wheel 121 may be in contact with the first rail. The first traveling wheel 121 may support the load of the substrate transfer apparatus. The second traveling part 130 may be positioned at the second upper position UP2 so that the substrate transfer apparatus moves along the first rail R1.

A lower surface of the drive plate 230 and an upper surface of the base plate 133 may be spaced apart by a predetermined distance. Specifically, the distance between the lower surface of the drive plate 230 and the upper surface of the base plate 133 may be referred to as d1. However, the present disclosure is not limited thereto, and the drive plate 230 may be in contact with the base plate 133.

The connection portion between the first link 221 and the second link 222 may face downward. That is, the connection portion between the first link 221 and the second link 222 may face the base plate 133. For example, a vertical level of the first joint 221b may be between a vertical level of the drive shaft 211a and a vertical level of the base plate 133. The connection portion between the drive plate 230 and the second link 222 may be spaced upward from the drive shaft 211a, which serves as the center of a rotational motion of the first link 221, by the difference between the first rotational radius r1 and the second rotational radius r2.

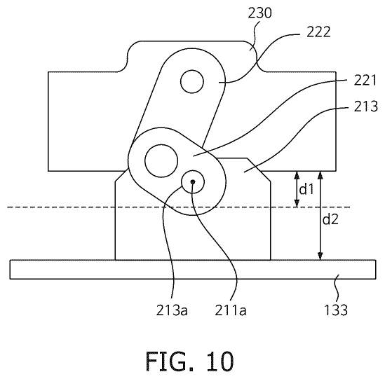

Referring to FIGS. 4 and 10, the first link 221 may be rotated by the drive device 210. For example, the first link 221 may rotate clockwise. The first link 221 may perform a repetitive rotational motion. However, the present disclosure is not limited thereto, and the first link 221 may rotate in either clockwise or counterclockwise direction. Depending on a method of controlling the drive motor 211, the direction and/or path of motion of the first link 221 may be varied. For example, the first link 221 may perform a reciprocating motion by rotating a certain section in the clockwise direction and rotating a certain section in the counterclockwise direction.

As the first link 221 rotates clockwise, the second link 222 may also rotate clockwise. The connection portion between the first link 221 and the second link 222 may move in the clockwise direction. Thus, the drive device 210 connected to the first link 221 and the second traveling part 130 coupled to the drive device 210 may move downwardly. That is, the second traveling part 130 may move to the second lower position LP2. In this case, the distance between the lower surface of the drive plate 230 and the upper surface of the base plate 133 may be d2, which is greater than d1.

With the first traveling wheel 121 of the first traveling part 120 in contact with the first rail R1, the second traveling wheel 131 of the second traveling part 130 may be in contact with the second rail R2. That is, at the intersecting point between the first rail R1 and the second rail R2, the first traveling wheel 121 and the second traveling wheel 131 may each be in contact with the first rail R1 and the second rail R2.

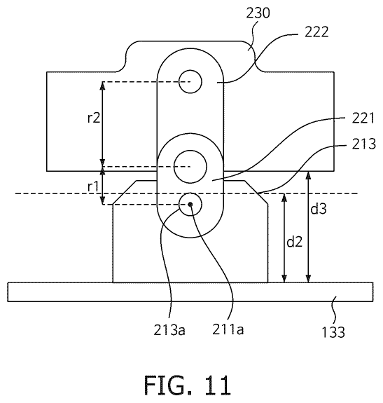

Referring to FIGS. 5 and 11, the first link 221 may be further rotated clockwise by the drive device 210. Accordingly, the connection portion between the first link 221 and the second link 222 may move in the clockwise direction. The connection portion between the drive plate 230 and the second link 222 may be spaced upward from the drive shaft 211a, which serves as the center of a rotational motion of the first link 221, by the sum of the first rotational radius r1 and the second rotational radius r2.

Since the second traveling part 130 connected to the drive device 210 is in contact with the second rail R2 to support the load, the drive device 210 and the second traveling part 130 may not be able to move further downwardly. Thus, as the connection portion between the first link 221 and the second link 222 moves in the clockwise direction, the connection portion between the second link 222 and the drive plate 230 may move upwardly. In this case, the distance between the lower surface of the drive plate 230 and the upper surface of the base plate 133 may be d3, which is greater than d2.

As the drive plate 230 moves upwardly, the first traveling part 120 coupled to the drive plate 230 may move upwardly. Since the second traveling wheel 131 of the second traveling part 130 is in contact with the second rail R2 to support the load, the first traveling part 120 may move upwardly. That is, the second traveling part 130 may be positioned at the second lower position LP2, and the first traveling part 120 may be positioned at the first upper position UP1. As such, as the elevation device 200 raises the first traveling part 120 and lowers the second traveling part 130, the substrate transfer apparatus is moved along the second rail R2.

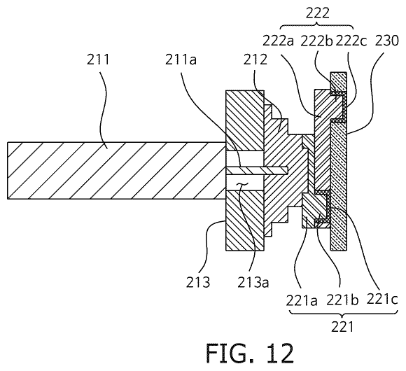

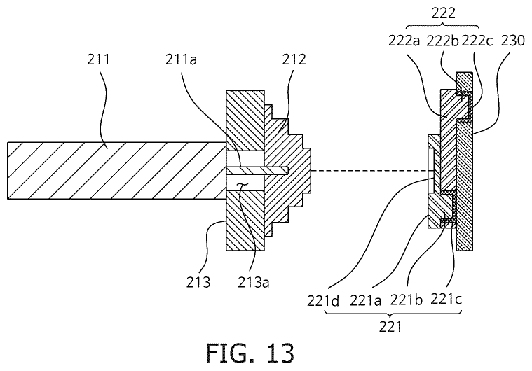

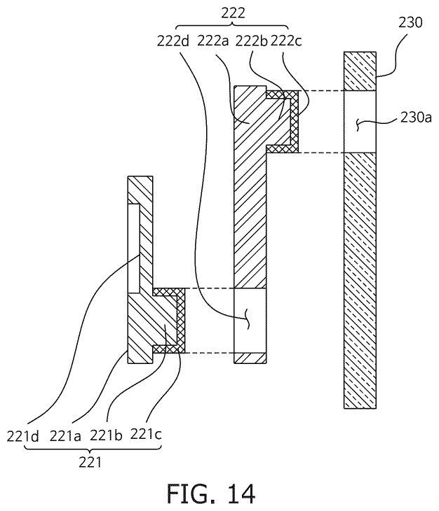

FIG. 12 is a cross-sectional view illustrating an elevation device in a coupled state according to some example embodiments. FIG. 13 is a cross-sectional view illustrating an elevation device with some components in a decoupled state according to some example embodiments. FIG. 14 is a cross-sectional view illustrating a link assembly in a disassembled state according to some example embodiments.

Referring to FIGS. 12 to 14, a structure capable of preventing particle generation in the substrate transfer apparatus will be described. In some example embodiments, the substrate transfer apparatus may be used in a semiconductor factory. A clean room in the semiconductor factory may require a high level of cleanliness. Therefore, the substrate transfer apparatus may require a structure that prevents generation of particles.

Referring to FIGS. 12 to 14, the elevation device 200 may include the drive device 210, the drive plate 230, and the link assembly 220.

In some example embodiments, the drive device 210 may have a structure that shields a portion where it is necessary to prevent particle generation. The drive motor 211 and the reducer 212 of the drive device 210 may be mechanically connected to each other. Specifically, the drive shaft 211a of the drive motor 211 may be connected to the reducer 212. A portion where the drive shaft 211a of the drive motor 211 is exposed, and a connection portion between the drive shaft 211a and the reducer 212 are places where particles may be generated due to friction, etc.

The drive motor 211 and the reducer 212 may be arranged with the housing 213 in between. The drive motor 211 may be coupled to one side of the housing 213, while the reducer 212 may be coupled to the other side of the housing 213. The housing 213 may have the shaft hole 213a formed therein for the drive shaft 211a to pass through. The drive motor 211 and the reducer 212 may be coupled in such a way that shields the portion where particle generation is likely. The exposed portion of the drive shaft 211a of the drive motor 211 may be disposed to face the shaft hole 213a of the housing 213. The connection portion between the reducer 212 and the drive shaft 211a may be disposed to face the shaft hole 213a of the housing 213. That is, the drive motor 211 and the reducer 212 may cover either end of the shaft hole 213a.

Referring to FIGS. 13 and 14, the elevation device in some example embodiments may prevent the generation of particles at a coupling portion between the reducer 212 and the first link 221. The reducer 212 and the first link 221 may be coupled to each other. As the first link 221 is coupled to the reducer 212, the first link body 221a may cover the reducer 212. Particles that may be generated at the coupling portion between the reducer 212 and the first link 221 may be prevented from spreading to the outside by the coupling structure of the reducer 212 and the first link 221.

The first link body 221a of the first link 221 may have a coupling portion 221d in which a portion of the reducer 212 is accommodated. The coupling portion 221d may be formed on the surface of the first link body 221a facing the reducer 212. The size and shape of the coupling portion 221d is not limited to that illustrated in the drawing and may be varied depending on the size and shape of the reducer 212.

Each of the first link 221 and the second link 222 of the link assembly 220 may include a first bearing 221c and a second bearing 222c. For example, the first bearing 221c and the second bearing 222c may be ball bearings. Note that the types of bearings are not limited to the above. Particles may be generated in the first bearing 221c and the second bearing 222c due to friction between an inner ring, an outer ring, balls disposed between the inner ring and the outer ring, etc.

The first joint 221b and the first bearing 221c of the first link 221 may be coupled to each other. The first bearing 221c may be covered by the first joint 221b and the first link body 221a. Additionally, the first joint 221b and the first bearing 221c, while being coupled together, may be accommodated in the joint hole 222d of the second link 222. The second link 222 may cover the coupling portion (e.g., the region of contact) between the first joint 221b and the first bearing 221c. That is, particles that may be generated in the first link 221 may be prevented from spreading to the outside by the coupling structure of the first joint 221b and the first bearing 221c, as well as by the covering of the second link 222.

The second joint 222b and the second bearing 222c of the second link 222 may be coupled to each other. The second bearing 222c may be covered by the second joint 222b and the second link body 222a. In addition, the second joint 222b and the second bearing 222c, while being coupled together, may be accommodated in the plate hole 230a of the drive plate 230. The drive plate 230 may cover the coupling portion (e.g., the region of contact) between the second joint 222b and the second bearing 222c. That is, particles that may be generated in the second link 222 may be prevented from spreading to the outside by the coupling structure of the second joint 222b and the second bearing 222c, as well as by the covering of the drive plate 230.

Although the present disclosure has been described above by way of certain embodiments and drawings, the present disclosure is not limited thereto, and various changes and modifications can be made within the equivalent scope of the technical idea of the present disclosure and the claims to be described below by those of ordinary skill in the art.

1. A substrate transfer apparatus, comprising:
a main body on which a carrier configured to store a substrate is loaded;
a first wheel assembly disposed inside the main body, the first wheel assembly being configured to travel along a first rail extending in a first direction to move the main body;
a second wheel assembly disposed inside the main body, the second wheel assembly being configured to travel along a second rail extending in a second direction different from the first direction to move the main body; and
a lift disposed inside the main body and configured to move the first wheel assembly up and down between a first lower position at which the first wheel assembly is in contact with the first rail and a first upper position higher than the first lower position, and to move the second wheel assembly up and down between a second lower position at which the second wheel assembly is in contact with the second rail and a second upper position higher than the second lower position.

2. The substrate transfer apparatus of claim 1, wherein the lift is configured to, when the lift is at an intersecting point between the first rail and the second rail:
lower the first wheel assembly from the first upper position to the first lower position and raise the second wheel assembly from the second lower position to the second upper position; or
lower the second wheel assembly from the second upper position to the second lower position and raise the first wheel assembly from the first lower position to the first upper position.

3. The substrate transfer apparatus of claim 1, wherein the lift comprises:
a drive motor comprising a drive shaft extending in the second direction and a drive motor configured to generate a rotational force, the drive motor being coupled to the second wheel assembly;
a drive plate coupled to the first wheel assembly; and
a link assembly coupled to the drive motor and the drive plate.

4. The substrate transfer apparatus of claim 3, wherein the link assembly comprises:
a first link coupled to the drive motor, the first link being configured to rotate about the drive shaft; and
a second link coupled to the first link and the drive plate and configured to move according to a rotation of the first link.

5. The substrate transfer apparatus of claim 4, wherein a rotation radius of the first link is smaller than a rotation radius of the second link.

6. The substrate transfer apparatus of claim 4, wherein
the first link comprises a first joint and a first bearing coupled to the first joint,
the second link comprises a joint hole, and
the first joint and the first bearing are accommodated in the joint hole.

7. The substrate transfer apparatus of claim 4, wherein
the second link comprises a second joint and a second bearing coupled to the second joint,
the drive plate comprises a plate hole, and
the second joint and the second bearing are accommodated in the plate hole.

8. The substrate transfer apparatus of claim 4, wherein the second link is connected to the drive plate and disposed between the first link and the drive plate.

9. The substrate transfer apparatus of claim 3, wherein the drive motor further comprises:
a housing coupled to the second wheel assembly and including a shaft hole formed therein; and
a reducer connected to the drive shaft,
wherein the housing is disposed between the drive motor and the reducer, and
wherein the drive motor and the reducer are configured to close the shaft hole.

10. The substrate transfer apparatus of claim 1, wherein
the first wheel assembly comprises:
a first shaft extending along the second direction; and
a first traveling wheel rotatably coupled to the first shaft, and
the second wheel assembly comprises:
a second shaft extending along the first direction; and
a second traveling wheel rotatably coupled to the second shaft.

11. The substrate transfer apparatus of claim 10, wherein the first traveling wheel and the second traveling wheel have different diameters from each other.

12. The substrate transfer apparatus of claim 10, wherein
the first wheel assembly further comprises a moving plate coupled with the first shaft and extending in the second direction,
the second wheel assembly further comprises a base plate coupled with the second shaft, and
the lift is coupled to the moving plate and is configured to cause a relative movement between the moving plate and base plate.

13. The substrate transfer apparatus of claim 12, further comprising a moving guide plate disposed on the base plate and configured to guide movement of the moving plate in a third direction perpendicular to the first direction and the second direction.

14. A substrate transfer apparatus, comprising:
a main body on which a carrier is configured to be loaded and which is configured to move in a first direction or a second direction perpendicular to the first direction;
a first wheel assembly disposed inside the main body, and comprising a first shaft extending in the second direction and a first traveling wheel rotatably coupled to the first shaft;
a second wheel assembly disposed inside the main body, and comprising a second shaft extending in the first direction and a second traveling wheel rotatably coupled to the second shaft; and
a lift disposed inside the main body and configured to move each of the first wheel assembly and the second wheel assembly up and down,
wherein the lift comprises:
a drive motor comprising a drive shaft extending in the second direction and a drive motor configured to generate a rotational force, the drive motor being coupled to the second wheel assembly;
a drive plate coupled to the first wheel assembly and extending in the first direction; and
a link assembly coupled to the drive motor and the drive plate.

15. The substrate transfer apparatus of claim 14, wherein
the second wheel assembly further comprises a base plate disposed under the main body and coupled with the second shaft, and
the lift is disposed on the base plate.

16. The substrate transfer apparatus of claim 15, wherein
the first wheel assembly further comprises a moving plate coupled with the first shaft, and
the substrate transfer apparatus further comprises a moving guide plate disposed on the base plate and configured to guide movement of the moving plate in a third direction perpendicular to the first direction and the second direction.

17. The substrate transfer apparatus of claim 16, wherein the link assembly comprises:
a first link configured to perform a rotational motion by the rotational force generated by the drive motor; and
a second link rotatably coupled to the first link.

18. The substrate transfer apparatus of claim 17, wherein
the first link comprises a first joint and a first bearing rotatably coupled to the first joint, and
a first region of contact between the first joint and the first bearing is covered by the second link.

19. The substrate transfer apparatus of claim 18, wherein
the second link comprises a second joint and a second bearing rotatably coupled to the second joint, and
a second region of contact between the second joint and the second bearing is covered by the drive plate.

20. A substrate transfer system, comprising:
a grid rail comprising a first rail extending in a first direction and a second rail extending in a second direction perpendicular to the first direction; and
a substrate transfer apparatus configured to move in the first direction or the second direction on the grid rail to transfer a substrate,
wherein the substrate transfer apparatus comprises:
a main body on which a carrier configured to store the substrate is loaded;
a first wheel assembly comprising a first shaft extending along the second direction, a first traveling wheel rotatably coupled to the first shaft, and a moving plate coupled with the first shaft, the first wheel assembly being configured to move the main body along the first rail;
a second wheel assembly comprising a second shaft extending along the first direction, a second traveling wheel rotatably coupled to the second shaft, and a base plate coupled with the second shaft, the second wheel assembly being configured to move the main body along the second rail; and
a lift configured to move the first wheel assembly up and down between a first lower position at which the first wheel assembly is in contact with the first rail and a first upper position higher than the first lower position, and to move the second wheel assembly up and down between a second lower position at which the second wheel assembly is in contact with the second rail and a second upper position higher than the second lower position.
